(19) United States
(12) Patent Application Publication
(10) Pub. No.: US 2026/0198241 A1
(43) Pub. Date: Jul. 9, 2026

(54) PLASMA PROCESSING METHOD

(71) Applicant: Hitachi High-Tech Corporation, Minato-ku, Tokyo (JP)

(72) Inventors: Junpei KIHARA, Tokyo (JP); Tomohiro TAKAMATSU, Tokyo (JP)

(21) Appl. No.: 18/838,430

(22) PCT Filed: Jul. 31, 2023
(86) PCT No.: PCT/JP2023/028025

§ 371 Date: Aug. 14, 2024

(51) Int. Cl. H10P 50/26; H01J 37/32; H10P 50/00

(52) U.S. Cl. CPC H10P 50/268; H01J 37/32146; H10P 50/71; H01J 2237/334

(57) ABSTRACT

To provide a plasma processing method capable of achieving both prevention of pattern collapse and vertical processing shape, a plasma processing method of plasma-etching a film to be etched using a carbon-containing film mask and an inorganic film mask is provided that includes: a first step of plasma-etching the film to be etched using the carbon-containing film mask and the inorganic film mask; a second step of trimming the carbon-containing film mask after the first step; and a third step of over-etching the film to be etched after the second step.

### TECHNICAL FIELD

The present invention relates to a plasma processing method of processing a semiconductor device using plasma.

### BACKGROUND ART

Pattern miniaturization has progressed year by year as a processing speed of a semiconductor device increases, and high-precision microfabrication technology is required as a pitch size decreases. In a so-called dry etching field in which a film to be processed is etched using plasma, a method of reducing a processing dimension of a material to be etched by trimming a carbon-based mask by dry etching before processing the material to be etched in order to perform miniaturization of a pattern has been generally performed (for example, see PTL 1). Pattern collapse is prevented by reducing a processing dimension during processing of a material to be etched (for example, see PTL 2).

### CITATION LIST

### Patent Literature

PTL 1: JP2013-89827A
PTL 2: JP2007-234870A

### SUMMARY OF INVENTION

### Technical Problem

In recent years, patterns with progressive reduction in pitch size have higher aspect ratios. When the carbon-based mask is trimmed using the technique described in PTL 1, since a carbon-based mask pattern becomes thinner, resistance to plasma is significantly reduced, and a probability that so-called pattern collapse occurs, in which semiconductor wiring collapses sideways due to etching of a semiconductor material that is a material to be etched, increases. Therefore, there is a limit to an amount of reduction in processing dimensions.

In the technique described in PTL 2, pattern collapse is insufficiently prevented for a high-aspect-ratio structure in recent years. When the above technique is used, etching does not easily proceed in a lower portion of a film to be etched, and a lower portion of a pattern expands in a width direction, and there is a concern that a so-called skirt shape may occur and vertical processing may not be possible.

An object of the invention is to provide a plasma processing method capable of achieving both prevention of pattern collapse and vertical processing shape.

### Solution to Problem

A configuration of the invention for achieving the above object is as follows.

A plasma processing method of plasma-etching a film to be etched using a carbon-containing film mask and an inorganic film mask, includes: a first step of plasma-etching the film to be etched using the carbon-containing film mask and the inorganic film mask; a second step of trimming the carbon-containing film mask after the first step; and a third step of over-etching the film to be etched after the second step.

### Advantageous Effects of Invention

According to the invention, it is possible to provide a plasma processing method capable of achieving both prevention of pattern collapse and vertical processing shape.

### BRIEF DESCRIPTION OF DRAWINGS

FIG. 1 is a schematic cross-sectional view of a plasma etching apparatus according to the invention.

FIGS. 2A and 2B are schematic diagrams showing a structure of a sample used in an embodiment of the invention.

FIG. 3 is a diagram showing progress of etching of a semiconductor substrate according to the embodiment of the invention.

FIG. 4 is a diagram showing progress of etching of a semiconductor substrate when a related art is used.

FIGS. 5A and 5B are diagrams showing a comparison of etching results between the related art and a technique according to the invention.

### DESCRIPTION OF EMBODIMENTS

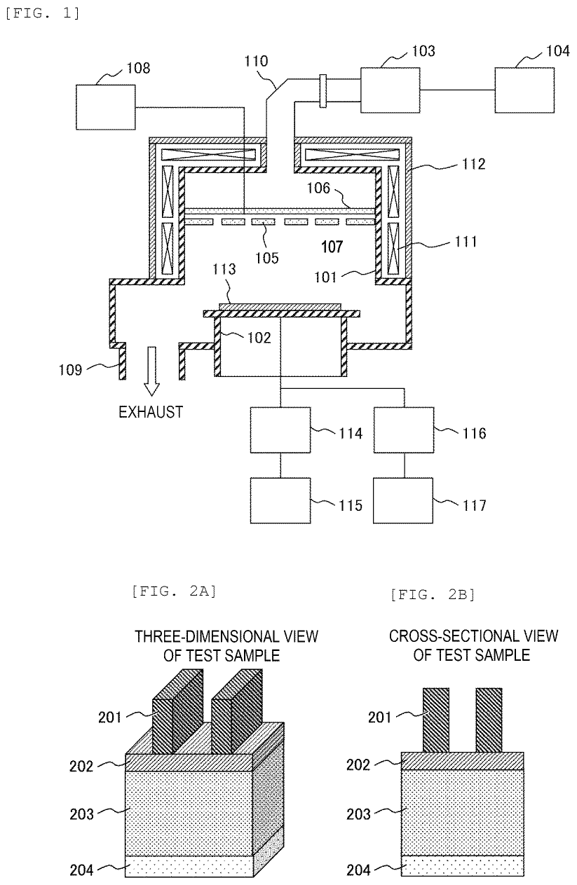

A plasma processing apparatus used in an embodiment of the invention will be described with reference to the drawings. FIG. 1 is a schematic longitudinal cross-sectional view showing an Electron Cyclotron Resonance (ECR) microwave plasma etching apparatus used in the present embodiment. A shower plate 105 (for example, made of quartz) for introducing processing gas into a vacuum container 101 whose upper portion is opened and a dielectric window 106 (for example, made of quartz) are disposed in an upper portion of the vacuum container 101, and a processing chamber 107 is formed by sealing.

A plurality of holes for supplying the processing gas are arranged in the shower plate 105, and the gas supplied from a gas supply apparatus 108 is introduced into the processing chamber 107 through the plurality of holes. A vacuum exhaust device (not shown) is connected to the vacuum container 101 via a vacuum exhaust port 109. In order to transmit power for generating plasma to the processing chamber 107, a wave guide 110 for transmitting electromagnetic waves is provided above the dielectric window 106.

A radio frequency (radio frequency for plasma generation) transmitted to the wave guide 110 is oscillated from an oscillator 103 under control of a first radio frequency power supply 104. Since the first radio frequency power supply 104 includes a pulse oscillator, it is possible to oscillate a time-modulated intermittent radio frequency or continuous radio frequency.

A frequency of the radio frequency is not particularly limited. In the present embodiment, a microwave of 2.45 GHz (radio frequency for plasma generation) is used. A magnetic field generating coil 111 for generating a magnetic field is provided at an outer peripheral portion of the processing chamber 107. Power oscillated by the oscillator 103 generates high-density plasma in the processing chamber 107 through interaction with the generated magnetic field.

The magnetic field generating coil 111 is covered by a coil case 112. A sample stage 102 is provided at a lower portion of the vacuum container 101 so as to face the shower plate 105. An electrode surface of the sample stage 102 is covered with a thermal spraying film (not shown), and a direct current power supply 117 is connected to the sample stage 102 via a radio frequency filter 116. Further, a second radio frequency power supply 115, which is a radio frequency power supply for bias, is connected to the sample stage 102 via a matching circuit (matching unit) 114.

A temperature controller (not shown) is also connected to the sample stage 102. The wafer 113 is conveyed to the processing chamber 107 of the vacuum container 101 by a conveyance unit (not shown) and is placed on the sample stage 102. The wafer 113, which is a sample conveyed into the processing chamber 107, is attracted onto the sample stage 102 by an electrostatic force of a DC voltage applied from the direct current power supply 117, and is adjusted in temperature.

After desired processing gas is supplied to the processing chamber 107 by the gas supply apparatus 108, an inside of the vacuum container 101 is controlled to a predetermined pressure via the vacuum exhaust device, and a radio frequency is supplied from the oscillator 103 into the processing chamber 107 to generate plasma in the processing chamber 107. By applying radio frequency power from the second radio frequency power supply 115 connected to the sample stage 102, ions are drawn from the plasma to the wafer 113, and the wafer is subjected to plasma processing (etching).

Since the second radio frequency power supply 115 includes a pulse oscillator, time-modulated intermittent radio frequency power or continuous radio frequency power can be applied to the sample stage 102.

### Embodiment 1

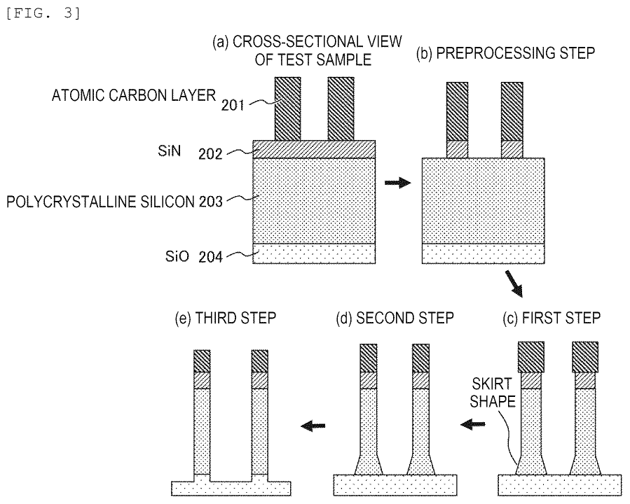

Hereinafter, an embodiment of the invention using the above-described plasma processing apparatus will be described. FIGS. 2A and 2B are schematic diagrams showing a structure of a sample used in the embodiment of the invention. FIG. 2A is a three-dimensional view of a test sample and has a line pattern structure. FIG. 2B is a cross-sectional view of the test sample.

An atomic carbon layer (ACL, film thickness: 100 nm) 201, SiN (film thickness: 40 nm) 202, Poly-Si (film thickness: 90 nm) 203, and SiO (film thickness: 300 nm) 204 are formed on/above a silicon substrate having a diameter of 12 inches. The ACL is a mask having a line pattern with a line width of 25 nm.

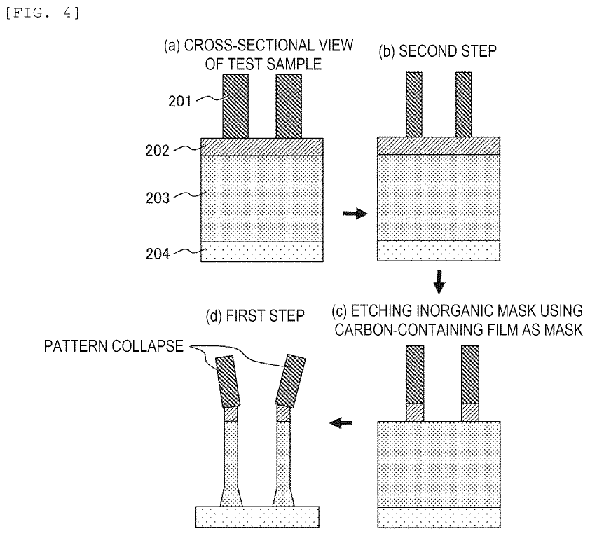

(a) of FIG. 3 and subsequent figures show a process of etching processing performed in one embodiment according to the invention. (b) of FIG. 3 shows a step of etching the SiN, which is an inorganic film mask using the ACL, which is a carbon-containing film as a mask (preprocessing for performing plasma processing, and hereinafter is referred to as “preprocessing” in some cases). (c) of FIG. 3 shows a first step according to the invention of etching the Poly-Si, which is a film to be etched, in a vertical direction (depth direction) and a lateral direction (width direction) using the ACL and the SiN as the masks. (d) of FIG. 3 shows a second step according to the invention of trimming the ACL, which is a carbon-containing film mask, to a width of the Poly-Si. (e) of FIG. 3 shows a third step according to the invention of over-etching the Poly-Si, which is the film to be etched.

Examples of processing conditions in the preprocessing step and the first to third steps according to the invention are shown in Table 1.

TABLE 1

| | | | | | | | | | | RF bias | |
|---|---|---|---|---|---|---|---|---|---|---|---|
| | Ar | He | —CHF₃ | CF₄ | SF₆ | N₂ | O₂ | Pressure | Microwave | Power | Duty |
| Step | (ml/min) | | | | | | | (Pa) | (W) | (W) | (%) |
| Preprocessing | 170 | | 70 | | | | 5 | 0.8 | 600 | 800 | 25 |
| step | | | | | | | | | | | |
| First step | | | | 60 | | 25 | 7 | 0.6 | 400 | 800 | 12 |
| Second step | 80 | | | | | 70 | 40 | 1.0 | 1200 | 10 | 100 |
| Third step | | 120 | | 60 | 6 | 25 | | 2.0 | 1200 | 600 | 50 |

In the preprocessing step, mixed gas of CHF₃, Ar, and O₂ is used as etching gas, and SiN, which is the inorganic film mask, is etched using the ACL as the mask. A content (vol %) of CHF₃, which is the etching gas in the mixed gas, is preferably 20% to 50% (in the conditions shown in Table 1, a content of CHF₃ is (70/(170+70+5))×100≈28.6%). If the content exceeds 50%, an etching rate becomes too high, which is not preferable. If the content is less than 20%, the etching rate is too slow and the process takes a long time. A pressure of the mixed gas is set to 0.8 Pa in Table 1, but etching can be performed under conditions of 0.1 Pa to 3.0 Pa, which is a pressure range of general etching gas.

From a viewpoint of shape control, execution power of an RF bias (an integrated value of power and duty, for example, when power is 800 W and duty is 25% shown in Table 1, execution power is 200 W) is preferably in a range of 100 W to 300 W. If the execution power is less than 100 W, it is difficult to ensure verticality of the etching. If the execution power is larger than 300 W, it is difficult to ensure a mask selection ratio.

Specific processing conditions of the steps according to the invention will be described below. In the first step according to the invention, mixed gas in which N₂ and O₂ are added to CF₄ as etching gas is used, and while etching of the Poly-Si, which is a material to be etched, in the vertical direction progresses using the ACL and the SiN as the masks, the SiN which is the inorganic film mask and the Poly-Si which is the material to be etched are etched in the lateral direction to reduce a pattern dimension. By adjusting a mixing proportion of N₂ and O₂, an etching ratio in the lateral direction with respect to the vertical direction can be adjusted. N₂ is preferably 10% to 30% (vol %) and O₂ is preferably 5% to 15% (vol %) (under the conditions shown in Table 1, N₂: about 27%, O₂: about 8%). From a viewpoint of in-plane uniformity, a processing pressure is preferably 0.4 Pa to 0.8 Pa. From the viewpoint of shape control, it is preferable to use a lower limit of a microwave output of 400 W to 600 W. If the output of the microwave is 600 W or more, deviation is strong and it is difficult to control a vertical shape. The power and the duty of the RF bias are preferably adjusted so that the execution power becomes 80 W to 120 W. If the execution power is smaller than 80 W, etching in the lateral direction is slower than etching in the vertical direction. If the execution power is larger than 120 W, etching in the lateral direction is faster than etching in the vertical direction, so a vertical shape cannot be obtained.

In the second step according to the invention, O₂, N₂ and Ar are used as etching gas, and a small RF bias (10 W in Table 1) is applied to trim the ACL mask, which is a carbon film mask, to a line width of 15 nm. A mixing proportion of O₂ is preferably 20% to 40% (vol %) from a viewpoint of etching rate control. For the RF bias, it is preferable to use an execution power of 5 W to 20 W from a viewpoint of uniformity of a trimming width. If the execution power is smaller than 5 W, there is a portion where trimming is slow due to adhesion of deposit. If the execution power is larger than 20 W, a height of the ACL mask is excessively reduced.

In the third step according to the invention, CF₄, SF₆, N₂, and He are used as etching gas, and Poly-Si as the material to be etched is over-etched using the ACL of the carbon film as the mask to remove a skirt shape of a lower portion of Poly-Si that occurs in the first step. As for a mixing proportion of the etching gas, it is preferable to use 15% to 30% (vol %) CF₄ and 30% to 60% (vol %) He to ensure the verticality of etching, and add 2% to 7% (vol %) SF₆ to ensure an etching rate and remove the skirt shape. It is preferable to use the RF bias with a duty of 25% or more in order to ensure the verticality of etching and the etching rate and remove the skirt shape. If the duty is less than 25%, it is difficult to remove the skirt shape and ensure the verticality. Since polysilicon is not etched in the lateral direction under etching conditions used here, a etching process is performed while maintaining a processing dimension formed in an upper layer.

### Comparative Example

FIG. 4 shows a shape in a case of etching using the related art. In the related art, when a line width of Poly-Si is reduced to 15 nm, the ACL mask is trimmed (second step) to thin the film before etching the SiN and the Poly-Si (first step). Therefore, when an aspect ratio of the ACL mask is increased, resistance to plasma is significantly reduced, and there is a problem that ACL mask collapse occurs during the etching of the Poly-Si (first step). There is a problem that a step due to a difference in reduction ratio occurs between the carbon-based mask (ACL) and the inorganic film (SiN and Poly-Si) during the etching of Poly-Si (first step), the step serves as a mask, a lower portion of Poly-Si is not etched, and a skirt shape occurs.

According to a feature of the invention, a pattern dimension can be reduced after the height of the ACL mask is reduced by performing trimming in the second step in the middle of the etching of Poly-Si according to the first step. Therefore, pattern collapse does not occur. Further, after the dimension of the ACL mask is reduced, over-etching, which is the third step, is performed to remove the skirt shape to obtain a vertical shape.

Accordingly, in this test, using a mask pattern showing an initial dimension of 25 nm, it was possible to implement a Poly-Si wiring process having a line width of 15 nm and a film thickness of 90 nm without disconnection and bending.

Similarly, when a Poly-Si wiring process with a line width of 15 nm and a film thickness of 90 nm is implemented by only trimming the initial ACL mask, which is processed under conditions in FIG. 4 which is the related art, a photoresist pattern of the ACL mask collapses during the etching of the Poly-Si, causing problems such as disconnection and bending of polysilicon wiring.

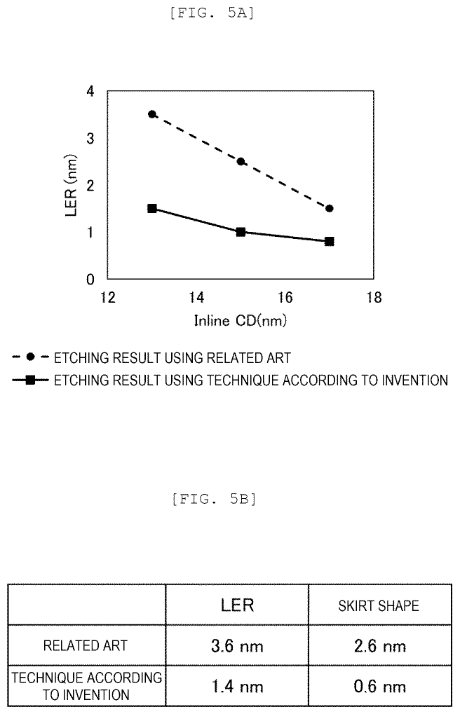

FIGS. 5A and 5B show a comparison between an etching result using the related art and an etching result using the technique according to the invention. In FIG. 5A, a horizontal axis shows an Inline CD indicating a pattern dimension and a vertical axis shows line edge roughness (LER) serving as an index of a size of pattern collapse. It can be seen that in the related art, the LER deteriorates more as the Inline CD becomes smaller, while in the technique according to the invention, deterioration of the LER is reduced.

FIG. 5B shows a comparison between the LER and the skirt shape in the related art and the technique according to the invention when the Inline CD is 15 nm in this test. By using the technique according to the invention, the LER was improved from 3.6 nm to 1.4 nm, and the skirt shape was improved from 2.6 nm in the related art to 0.6 nm. Therefore, according to the technique according to the invention, the pattern collapse and the skirt shape were reduced.

The present embodiment is a process condition in which optimization is performed on a test sample of a semiconductor device. Processing methods of the Poly-Si, the SiN, and the ACL are not limited to the present implementation conditions.

Although the invention has been described with respect to a Poly-Si wiring processing step, the invention is not limited thereto. In a semiconductor device manufacturing step, a method of the invention can also be applied to a wiring process of a material other than the PolySi, for example, the method of the invention can be applied to wiring processes of Si, SiN, SiO, SiON, TiN, and WSi. A process of an inorganic film as the mask is not limited to the SiN, and may be applied to, for example, processes of Si, SiO, SiON, TiN, and WSi. It is preferable to obtain a suitability value of gas or a processing condition used according to a material to be processed.

Although the invention uses a plasma etching apparatus using a microwave and a magnetic field, the invention can be applied regardless of a plasma generation method. For example, a similar effect can be obtained even when the invention is carried out by using a helicon wave etching apparatus, an inductively coupled etching apparatus, a capacitively coupled etching apparatus, or the like.

### REFERENCE SIGNS LIST

101: vacuum container
102: wafer placement electrode
103: electromagnetic wave generation power supply
104: first radio frequency power supply
105: shower plate
106: dielectric window
107: processing chamber
108: gas supply apparatus
109: vacuum exhaust port
110: wave guide
111: magnetic field generating coil
112: coil case
113: wafer
114: matching circuit
115: second radio frequency power supply
116: radio frequency filter
117: direct current power supply
201: carbon-based film
202: inorganic film
203: film to be etched
204: base film

1. A plasma processing method of plasma-etching a film to be etched using a carbon-containing film mask and an inorganic film mask, the plasma processing method comprising:
a first step of plasma-etching the film to be etched using the carbon-containing film mask and the inorganic film mask;
a second step of trimming the carbon-containing film mask after the first step; and
a third step of over-etching the film to be etched after the second step.

2. The plasma processing method according to claim 1, wherein
the second step reduces a dimension of the inorganic film mask.

3. The plasma processing method according to claim 1, wherein
radio frequency power supplied to a sample stage on which a sample having the film to be etched is placed in the third step is larger than radio frequency power in the first step, or
a duty proportion of pulse-modulated radio frequency power supplied to the sample stage in the third step is larger than a duty proportion in the first step.

4. The plasma processing method according to claim 1, wherein
the inorganic film is a silicon nitride film (SiN), a silicon film (Si), or a silicon oxide film (SiO).

5. The plasma processing method according to claim 1, wherein
the film to be etched is a polysilicon film (Poly-Si).

6. The plasma processing method according to claim 1, wherein
the inorganic film is a silicon nitride film (SiN), and
the film to be etched is a polysilicon film (Poly-Si).

7. The plasma processing method according to claim 1, wherein
plasma in the first step is generated by mixed gas of fluorine-containing gas, N₂ gas, and O₂ gas.

8. The plasma processing method according to claim 6, wherein
plasma in the first step is generated by mixed gas of fluorine-containing gas, N₂ gas, and O₂ gas.

9. The plasma processing method according to claim 7, wherein
the fluorine-containing gas is CF₄ gas.

10. The plasma processing method according to claim 8, wherein
the fluorine-containing gas is CF₄ gas.

11. The plasma processing method according to claim 5, wherein
the over-etching is performed using plasma generated by mixed gas of CF₄ gas, He gas, SE₆ gas, and N₂ gas.
